(19) United States
(12) Patent Application Publication
(10) Pub. No.: US 2009/0130604 A1
(43) Pub. Date: May 21, 2009

(54) Solution for immersion exposure and immersion exposure method

(75) Inventors: Akifumi Kagayama, Chiba (JP); Norio Nakayama, Chiba (JP); Hiroaki Tamatani, Kanagawa (JP)

Correspondence Address: BUCHANAN, INGERSOLL & ROONEY PC, POST OFFICE BOX 1404, ALEXANDRIA, VA, 22313-1404, US

(73) Assignee: Mitsui Chemicals, Inc., Minato-ku, Tokyo (JP)

(21) Appl. No.: 11/991,106

(22) PCT Filed: Aug. 22, 2006
(86) PCT No.: PCT/JP2006/316432

§ 371 Date: Feb. 27, 2008

(30) Foreign Application Priority Data
Aug. 29, 2005 (JP) 2005-248232

(51) Int. Cl. G03F 7/20; C09K 3/00

(52) U.S. Cl. 430/322; 252/582

(57) ABSTRACT

The object is to resolve a finer pattern with a narrower line/space width by immersion lithography technology in the manufacture of a semiconductor or the like. A liquid for use in immersion exposure includes a saturated hydrocarbon compound as a main component, wherein the content of an impurity or impurities having an unsaturated bond or a heteroatom in its structure is respectively as follows: (i) 2 μg/mL or less in total for a compound having a conjugated unsaturated bond; (ii) 30 μg/mL or less in total for a compound having no conjugated unsaturated bond but having a non-conjugated unsaturated bond; (iii) 15 μg/mL or less in total for amines having no unsaturated bond; and (iv) 100 μg/mL or less in total for a heterocyclic compound, alcohols, ethers and a halogen-containing compound, other than above compounds (i) to (iii).

### TECHNICAL FIELD

The present invention relates to a liquid for immersion exposure and an immersion exposure method, particularly a technique used for an immersion exposure device, which employs a liquid provided in an optical path in between a projection optical system and a substrate which to be served as an electronic device upon an exposure in a projection exposure device used in a lithography process for manufacturing various electronic devices such as semiconductor integrated circuits.

### BACKGROUND ART

In accordance with higher integration and higher density of various electronic devices, the patterns formed by the lithography process have been made finer. In the advanced process, by the use of ArF laser of a wavelength of 193 nm, a resolution of a pattern with a line/space width of about 90 to 65-nm half-pitch node has become possible.

The higher integration and higher density of electronic devices have been increasingly demanded, and the formation of finer pattern in the lithography process has been also required. For the formation of the finer pattern in the lithography process, the wavelength of exposure light is reduced in general, and for the region finer than 65-nm half-pitch, the development of the device employing F₂ laser, EUV (extreme ultraviolet), or the like has been proceeded. However, a development on the transparent lenses for such wavelengths has been the difficulty resulting in high cost for the optical system, or the like, thereby leaving to many problems.

As the other means for the formation of finer pattern, there may be employed an increase of NA (numerical aperture) of lens. For increasing NA, the method of enlarging incident angle of exposure light by the projection lens is usually employed. However, there are problems in such case that there is a limitation on the incident angle due to a refractive index difference between lens and air, and that DOF (depth of focus) decreases.

On the other hand, there has been proposed an immersion exposure method as a means for increasing NA without decreasing DOF by employing a traditional projection optical system, that is, even if under a condition of the same wavelength of the exposure light (Patent Document 1). In the method, a liquid having a refractive index higher than that of a gas such as air or nitrogen gas is at least provided in some part between a lens and a substrate upon an exposure. Provided that the refractive index of the liquid is n, the wavelength of the exposure light in the liquid becomes 1/n as compared with that of the traditional dry exposure method employing only air or nitrogen gas, thus the incident angle can be increased thereby improving the resolution, and DOF can be also increased, even if the light source with the same exposure wavelength is used.

According to the immersion exposure method employing pure water (refractive index of 1.44) as the liquid having a high refractive index, it is possible to obtain a resolution for a pattern with a line/space of about 45-nm half-pitch using ArF Laser as a light source, and various related techniques have already been disclosed (Patent Document 2).

As for the finer region, a pattern with a line/space of about 40 to 30-nm half pitch has been required. In order to achieve the pattern using an ArF exposure, it has been desired to use a liquid exhibiting a refractive index of 1.6 or more for the light with wavelength of 193 nm. In addition, in order to maintain an excellent exposure performance showing a little influence by heat caused by laser, it is necessary that the transparency is high in the same wavelength of 193 nm, and that the transmittance for the film having a thickness of 1 mm is 80% or more, preferably 90% or more.

As the liquid exhibiting higher refractive index as compared with pure water, a fluorinated solvent of which the application is considered as same as the pure water is highly taken into account (Patent Document 3) in immersion exposure technique of about up to the 45-nm half-pitch which is at present in the course of development, due to a high transparency in the short wavelength region. However, in general, the compound having fluorine in the structure exhibiting a low refractive index, and the compound satisfying the targeted refractive index of 1.6 has been not yet discovered.

Further, there have been reported studies where water to which an inorganic compound is added, or an organic solvent is employed (Non-Patent Documents 1 and 2). However, there are still problems as follows. That is, as the water added with an inorganic compound, an aqueous solution of phosphoric acid or the like may be exemplified, but even if these satisfy the refractive index of 1.6, these exhibit low transmittance, and there may be a possibility that the additives pollute or corrode the lens or substrate. Also in the organic solvent system, in the case of alcohols such as glycerol (refractive index of 1.6), even if the high refractive index is exhibited, the transmittance is low due to an absorption property at around 190 nm.

[Patent Document 1] Japanese Patent Laid-Open No. 6-124873

[Patent Document 2] Japanese Patent Laid-Open No. 2005-19616

[Patent Document 3] Japanese Patent Laid-Open No. 2004-325466

[Non-Patent Document 1] Brucc W. Smith and five other, “Approaching the numerical aperture of water-immersion lithography at 193 nm”, Proceedings of SPIE, Year 2004, Vol. 5377, p. 273 to 284.

[Non-Patent Document 2] Simon G. Kaplan and John H. Burnett, “Characterization of refractive properties of fluids for immersion photolithography”, International Symposium on Immersion and 157 nm Lithography, Year 2004, second to fifth of August.

### DISCLOSURE OF THE INVENTION

The present invention is made in the light of these considerations, and the invention provides a material exhibiting high optical transmittance of and high refractive index with wavelength of ArF laser, as the liquid for immersion exposure.

The inventors of the present invention have devotedly conducted investigations in order to solve the problems, and as a result, they have found that in the saturated hydrocarbon compound of which the amount of impurities is controlled, those exhibiting high transmittance of and refractive index with wavelength of 193 nm can be obtained, thus completing the invention.

That is, the present invention relates to:

[1] a liquid for immersion exposure containing a saturated hydrocarbon compound as the main component,

wherein the content of an impurity or impurities having an unsaturated bond or a heteroatom in its structure is respectively as follows:

(i) 2 μg/mL or less in total for a compound having a conjugated unsaturated bond;

(ii) 30 μg/mL or less in total for a compound having no conjugated unsaturated bond but having a non-conjugated unsaturated bond;

(iii) 15 μg/mL or less in total for amines having no unsaturated bond; and

(iv) 100 μg/mL or less in total for a heterocyclic compound, alcohols, ethers and a halogen-containing compound, other than above compounds (i) to (iii);

[2] the liquid for immersion exposure as described in [1],

wherein the content of an impurity or impurities is 100 μg/mL or less in total for above compounds (i) to (iv);

[3] the liquid for immersion exposure as described in [1] or [2],

wherein the impurity is at least one selected from the group consisting of an aromatic compound, a heterocyclic compound, alkenes, alkynes, alcohols, ethers, a carbonyl compound, a halogen-containing compound, and amines;

[4] the liquid for immersion exposure as described in [1] or [2],

wherein the heterocyclic compound is at least one selected from the group consisting of an oxygen-containing cyclic compound, a sulfur-containing cyclic compound, and a nitrogen-containing cyclic compound;

[5] the liquid for immersion exposure as described in [1] or [2],

wherein the saturated hydrocarbon compound which is the main component is trans-decahydronaphthalene;

[6] the liquid for immersion exposure as described in [1] or [2],

wherein the saturated hydrocarbon compound which is the main component is trans-decahydronaphthalene,

above (i) compound having a conjugated unsaturated bond is at least one selected from the group consisting of toluene, tetrahydronaphthalene, and a phthalic esters;

above (ii) compound having no conjugated unsaturated bond but having a non-conjugated unsaturated bond is octenes; and

above (iv) a heterocyclic compound, alcohols, ethers and a halogen-containing compound, other than above compounds (i) to (iii) is cyclohexanols;

[7] the liquid for immersion exposure as described in [1] or [2],

wherein the saturated hydrocarbon compound which is the main component is bicyclohexyl;

[8] the liquid for immersion exposure as described in [1] or [2],

wherein the saturated hydrocarbon compound which is the main component is bicyclohexyl,

above (i) compound having a conjugated unsaturated bond is at least one selected from the group consisting of biphenyl, cresols, and phthalic esters;

above (ii) compound having no conjugated unsaturated bond but having a non-conjugated unsaturated bond is methyl cyclohexane carboxylic acid; and

above (iv) a heterocyclic compound, alcohols, ethers and a halogen-containing compound, other than above compounds (i) to (iii) is at least one selected from the group consisting of tetrahydrofuran, cyclohexyl methanol, and n-butanol; and

[9] an immersion exposure method employing the liquid for immersion exposure as described in any one of [1] to [8].

### BEST MODE FOR CARRYING OUT THE INVENTION

A liquid for immersion exposure according to the invention contains a saturated hydrocarbon compound as the main component, wherein the content of an impurity or impurities having an unsaturated bond or a heteroatom in its structure is as follows:

(i) 2 μg/mL or less in total for a compound having a conjugated unsaturated bond;

(ii) 30 μg/mL or less in total for a compound having no conjugated unsaturated bond but having a non-conjugated unsaturated bond;

(iii) 15 μg/mL or less in total for amines having no unsaturated bond; and

(iv) 100 μg/mL or less in total for a heterocyclic compound, alcohols, ethers and a halogen-containing compound, other than above compounds (i) to (iii). Hereinafter, the liquid for immersion exposure may be also referred to as “liquid for immersion exposure (a)”.

For the invention, among impurities in the liquid for immersion exposure, the concentration of each substance classified into above (i) to (iv) is not more than the predetermined concentration. Providing a plural kind of impurities with the predetermined concentration or less, respectively, the liquid for immersion exposure exhibiting transmittance of 80%/mm or more of and high refractive index with wavelength of 193 nm can be stably obtained.

From the view point of further improving the resolution, the refractive index of the liquid for immersion exposure (a) is for example, 1.5 or more, preferably 1.6 or more, and more preferably 1.63 or more.

In addition, from the view point of further increasing the transmittance and refractive index of the liquid for immersion exposure (a), it is preferable that the content of an impurity or impurities having an unsaturated bond or a heteroatom in its structure classified into the above (i) to (iv) is 100 μg/mL or less in total and each impurity concentration of (i) to (iv) is in the above range.

The saturated hydrocarbon compound used for the liquid for immersion exposure (a) in the invention is not particularly limited, but will be represented in detail as follows.

The saturated hydrocarbon compound is preferably for example, a linear or branched chain saturated hydrocarbon compound having 12 or more carbon atoms or a saturated hydrocarbon compound having 7 or more carbon atoms containing a cyclic backbone structure.

The linear or branched chain compound is a compound represented by the formula CₙH₂ₙ₊₂ (n is a natural number, same applies below), and n is preferably 12 or more. Specific examples of the compound include dodecanes such as n-dodecane, 2-methylundecane, 3-ethyldecane, 4-propylnonane, and 2,2,4,6,6-pentamethylheptane (isododecane), tridecanes, tetradecanes, pentadecanes, and hexadecanes.

The compound containing a cyclic backbone may include a monocyclic structure or polycyclic structure, also a linear or branched chain substituent, and the compound is represented by the formulae such as CₙH₂ₙ (monocyclic), CₙH₂ₙ₋₂ (bicyclic), CnH₂ₙ₋₄ (tricyclic), wherein n is preferably 7 or more. Among the compound in which n is 7 or more, as the monocyclic compound, cycloalkane such as cycloheptane, cyclooctane, and cyclodecane may be exemplified. As the bicyclic compound, a condensed-ring compound such as octahydroindene and decahydronaphthalene, an assembled ring compound such as bicyclohexyl, a bridged-ring compound such as norbornene, or the like, may be exemplified. As the tricyclic compound, a condensed-ring compound such as dodecahydrofluorene and tetradecahydrophenanthrene, or the like, may be exemplified.

Among these, more preferred compound may be exemplified by isododecane, decahydronaphthalene, cyclooctane, bicyclohexyl, or the like, and even more preferred compound is decahydronaphthalene or bicyclohexyl.

In addition, the saturated hydrocarbon compound may be used alone or in combination of a plurality of compounds.

The concentration of the saturated hydrocarbon compound which being the main component in the liquid for immersion exposure (a), that is, the purity of the main component, is preferably 99.0% by weight or more, more preferably 99.5% by weight or more, and even more preferably 99.9% by weight or more, from the view point of further increasing the transmittance in the wavelength of 193 nm.

Herein, the purity of the saturated hydrocarbon compound which being the main component refers to the ratio of the saturated hydrocarbon compound which being the main component to the whole liquid for immersion exposure. The saturated hydrocarbon compound may be one or plural kinds, and in the case of plural kinds, the ratio of the saturated hydrocarbon compound contained as the main component to the whole liquid for immersion exposure indicates the purity.

The saturated hydrocarbon compound used in the invention has high stability to light, heat, oxygen, and the like, low toxicity and corrosivity, and thus the handling is easy and may be available or synthesized at industrially low price. Accordingly, the saturated hydrocarbon compound can be applied to the immersion lithography technology using the purified water now being developed, without significant change of technique and cost.

In addition, according to the invention, the liquid for immersion exposure exhibiting high refractive index and high optical transmittance can be obtained. In the immersion exposure method using the liquid for immersion exposure of the present invention, the finer resolution becomes possible, even if when the traditional exposure device is employed. In particular, by applying the liquid for immersion exposure of the invention to the ArF immersion exposure device which is in the course of development, for example, a pattern with a line/space of about 40 to 30-nm half-pitch which is required for a next generation electronic device can be easily achieved. Thus, the invention is highly industrially valuable.

Herein, the impurity in the saturated hydrocarbon compound defined in the invention is a group of compounds which may be coexisted either in the commercial product or upon the production from coal, petrochemical product, or the like, or a group of compounds which may be incorporated from a resist during the exposure process, and specific examples thereof will be represented below. In addition, a metal and an ionic impurity are usually not contained in the commercially available saturated hydrocarbon compound, as they can be easily removed.

In the invention, among the impurity in the liquid for immersion exposure, the compound set to the predetermined concentration or less is a substance containing an unsaturated bond or a heteroatom in its structure. The substances are classified in the following (i) to (iv):

(i) a compound having a conjugated unsaturated bond;

(ii) a compound having no conjugated unsaturated bond but having a non-conjugated unsaturated bond;

(iii) amines having no unsaturated bond; and

(iv) a heterocyclic compound, alcohols, ethers and a halogen-containing compound, other than above compounds (i) to (iii).

(i) The compound having a conjugated unsaturated bond may be exemplified by an aromatic compound, a conjugated diene, or α,β-unsaturated carbonyl compound.

Examples of the aromatic compound include an aromatic hydrocarbon compound such as benzene, toluene, xylene, naphthalene, tetrahydronaphthalene, biphenyl, fluorene, anthracene, and phenanthrene;

an aromatic compound of which the functional group is substituted such as phenol, cresol, and 2,6-di-tert-butyl-p-cresol, and phthalic esters such as catechol, benzyl alcohol, aniline, aminonaphthalene, benzenethiol, benzoic acid, bis(2-ethylhexyl) phthalate, and the like.

Examples of the conjugated dienes include butadiene, isoprene and the like.

Examples of α,β-unsaturated carbonyl compound include acrylic esters or the like.

The total concentration of (i) the compound having a conjugated unsaturated bond in the liquid for immersion exposure is 2 μg/mL or less, preferably 1 μg/mL or less, and more preferably 0.1 μg/mL or less.

(ii) The compound having no conjugated unsaturated bond but having a non-conjugated unsaturated bond may be exemplified by alkenes, alkynes, a carbonyl compound, other than above compound (i).

Among these, examples of the alkenes include terminal olefins such as 1-hexene and 1-octene;

internal olefins such as 2-octene;

cyclic olefins such as cyclohexene; and

dienes and trienes thereof, and the like.

Examples of the alkynes include 1-hexine, 1-octine or the like.

Examples of the carbonyl compound include aldehydes such as hexanal, benzaldehyde, and the like;

ketones such as acetone, 2-butanone, and acetophenon;

carboxylic acids such as acetic acid; esters such as ethyl acetate, methyl cyclohexane carboxylate; and

a compound having each functional group in a plurality of the combinations or the like.

The total concentration of (ii) the compound having no conjugated unsaturated bond but having a non-conjugated unsaturated bond in the liquid for immersion exposure is 30 μg/mL or less, preferably 10 μg/mL or less, and more preferably 1 μg/mL or less.

(iii) The amines having no unsaturated bond may be exemplified by triethylamine, hexylamine or the like. The total concentration of the amines having no unsaturated bond in the liquid for immersion exposure is 15 μg/mL or less, preferably 5 μg/mL or less, and more preferably 0.5 μg/mL or less.

Among (iv) the heterocyclic compound, the alcohols, the ethers and the halogen-containing compound, other than above compounds (i) to (iii), examples of the heterocyclic compound include an oxygen-containing cyclic compound such as furan, pyran, tetrahydrofuran, and dioxane;

a sulfur-containing cyclic compound such as thiophene and tetrahydrothiophene; and

a nitrogen-containing cyclic compound such as pyrrole, pyridine, pyrrolidine, piperidine, and piperazine, and the like.

Examples of the alcohols include linear chain alcohols such as methanol, ethanol, n-butanol, and n-octanol;

cyclohexanols such as cyclohexanol, cyclohexylmethanol, and dimethylcyclohexanol, and the other cyclic alcohols.

In addition, monoalcohol is exemplified in the above, but the number of the hydroxyl group in the molecule is not particularly limited, and include in addition to the above,

diols such as ethylene glycol; and

triols such as glycerol.

Examples of the ethers include diethyl ether, diisopropyl ether, dimethoxy ethane or the like.

Examples of the halogen-containing compound include chloroform, bromobenzene, iodobenzene and the like.

The total concentration of (iv) the heterocyclic compound, the alcohol, the ether and the halogen-containing compound, other than above compounds (i) to (iii) in the liquid for immersion exposure is 100 μg/mL or less, preferably 50 μg/mL or less, and more preferably 3 μg/mL or less.

The impurity in the liquid for immersion exposure of the invention is at least one selected from the group consisting of an aromatic compound, a heterocyclic compound, alkenes, alkynes, alcohols, ethers, a carbonyl compound, a halogen-containing compound, and amines.

For the invention, as a specific combination of the saturated hydrocarbon compound being the main component and the impurity, following embodiments, for example, may be mentioned:

an embodiment in which the saturated hydrocarbon compound being the main component is trans-decahydronaphthalene; (i) the compound having a conjugated unsaturated bond is at least one selected from the group consisting of toluene, tetrahydronaphthalene, and phthalic esters; (ii) the compound having no conjugated unsaturated bond but having a non-conjugated unsaturated bond is octenes; and (iv) the heterocyclic compound, alcohols, the ethers and the halogen-containing compound, other than above compounds (i) to (iii) is cyclohexanols; and

another embodiment in which the saturated hydrocarbon compound being the main component is bicyclohexyl, (i) the compound having a conjugated unsaturated bond is at least one selected from the group consisting of biphenyl, cresols, and phthalic esters; (ii) the compound having no conjugated unsaturated bond but having a non-conjugated unsaturated bond is methyl cyclohexane carboxylic acid; and (iv) the heterocyclic compound, the alcohols, the ethers and the halogen-containing compound, other than above compounds (i) to (iii) is at least one selected from the group consisting of tetrahydrofuran, cyclohexyl methanol, and n-butanol.

As the preferred embodiment of the invention, the following liquid for immersion exposure (b) may be exemplified, and more preferred embodiment may be exemplified by the following liquid for immersion exposure (c).

Liquid for Immersion Exposure (b):

A liquid for immersion exposure (b) contains a saturated hydrocarbon compound as the main component,

wherein the content of an impurity or impurities having an unsaturated bond or a heteroatom in its structure is respectively as follows:

(i) 1 μg/mL or less in total for a compound having a conjugated unsaturated bond;

(ii) 10 μg/mL or less in total for a compound having no conjugated unsaturated bond but having a non-conjugated unsaturated bond;

(iii) 5 μg/mL or less in total for amines having no unsaturated bond; and

(iv) 50 μg/mL or less in total for a heterocyclic compound, alcohols, ethers and a halogen-containing compound, other than compounds (i) to (iii).

According to the liquid for immersion exposure (b), there can be stably obtained those exhibiting high transmittance and refractive index, that is the transmittance of 90%/mm or more of and the refractive index of 1.63 or more, for example, for the light with wavelength of 193 nm.

In addition, from the view point of further increasing transmittance and refractive index of the liquid for immersion exposure (b), it is preferable that the content of an impurity or impurities having an unsaturated bond or a heteroatom in its structure classified into the above (i) to (iv) is 50 μg/mL or less in total and each impurity concentration of the compounds (i) to (iv) is in the above range.

Liquid for Immersion Exposure (c):

A liquid for immersion exposure (c) contains a saturated hydrocarbon compound as the main component, wherein the content of an impurity or impurities having an unsaturated bond or a heteroatom in its structure is respectively as follows:

(i) 0.1 μg/mL or less in total for a compound having a conjugated unsaturated bond;

(ii) 1 μg/mL or less in total for a compound having no conjugated unsaturated bond but having a non-conjugated unsaturated bond;

(iii) 0.5 μg/mL or less in total for amines having no unsaturated bond; and

(iv) 3 μg/mL or less in total for a heterocyclic compound, an alcohol, an ether and a halogen-containing compound, other than above compounds (i) to (iii).

According to the liquid for immersion exposure (c), there can be stably obtained those exhibiting high transmittance and refractive index, that is the transmittance of 98%/mm or more and the refractive index of 1.63 or more, for example, for the light with wavelength of 193 nm.

In addition, from the view point of further increasing transmittance and refractive index of the liquid for immersion exposure (c), it is preferable that the content of an impurity or impurities having an unsaturated bond or a heteroatom in its structure classified into the above (i) to (iv) is 3 μg/mL or less in total and each impurity concentration of (i) to (iv) is in the above range.

Next, the process for producing the liquid for immersion exposure of the invention will be explained. The liquid for immersion exposure (a) may be obtained in any process, as long as the impurity of above compounds (i) to (iv) is in the above mentioned concentration range.

The synthesis process and purification process of the saturated hydrocarbon compound used for the liquid for immersion exposure are not particularly limited, but by subjecting a commercial product or a product synthesized by hydrogen reduction or the like of the compound constituted of the same carbon backbone and having unsaturated bond, to an activated carbon treatment, silica gel column chromatography, distillation, or the like, the saturated hydrocarbon compound having high purity can be obtained.

However, it is difficult that the liquid for immersion exposure (a) is stably obtained by the above mentioned traditional process. This is because, in order to obtain the liquid for immersion exposure (a), the concentration of the above impurities (i) to (iv) has to be the predetermined value or below, which causes problems such that the number of process is increased, yield is reduced, or the like, upon distillation because impurities having boiling points near to the raw material or impurities giving an azeotropic mixture with the main component has to be the predetermined value or below. As to be described in Example section later, in the case of using the commercially available saturated hydrocarbon compound as the raw material, by only filtering with silica gel, it is impossible that concentration of all impurities of (i) to (v) is adjust to the predetermined value or less. Accordingly, it is impossible to sufficiently increase the transmittance with respect to exposure light.

On the other hand, in the invention, the predetermined absorbent is selectively used according to the kind of the saturated hydrocarbon compound and impurity, and the saturated hydrocarbon compound is brought into contact with a plurality of various kinds of the absorbents. Even in the case where a plurality of impurity components which are necessary to be removed is present in the liquid serving as the raw material of the liquid for immersion exposure, and thus the removal of all impurity components by one absorbent becomes difficult, by the use of a plurality of absorbents in combination, a plurality of impurity components having different properties can be removed efficiently in one process. As a result, the purity of the saturated hydrocarbon compound can be further increased. Accordingly, it becomes possible for the concentration of impurities (i) to (iv) to be the predetermined value or below, and thus the liquid for immersion exposure (a) exhibiting high refractive index and high transmittance can be easily obtained.

In particular, it is difficult that the liquid for immersion exposure (c) is stably obtained only by general distillation and acid treatment, the liquid for immersion exposure (c) is stably obtained only by using a plurality of absorbents in combination and repeating the absorption operation as necessary.

Hereinafter, the purification process of the liquid for immersion exposure using a plurality of absorbent will be further explained in detail.

Here, the saturated hydrocarbon compound is brought into contact with the first and second absorbents to obtain the liquid for immersion exposure containing the saturated hydrocarbon compound having the impurity concentration in the range of the above mentioned or less. The process of bring the saturated hydrocarbon compound into contact with the first absorbent and the process of bring the saturated hydrocarbon compound into contact with the second absorbent may be the same process or different process. The second absorbent may be those having a function as a filtering medium capable of physically filtering fine particles, the first absorbent, and the like contained in the liquid to be separated.

For example, the saturated hydrocarbon compound may be brought into contact with the first absorbent, as well as brought into contact with the second absorbent, by mixing the first absorbent and the second absorbent to brought contact with the saturated hydrocarbon compound. In addition, there may be carried out a process including bringing the saturated hydrocarbon compound into contact with the first absorbent, and then bringing to the contact with the second absorbent, wherein the first absorbent and the second absorbent are placed in the separate spaces.

In addition, the contact of the absorbent may be carried out by the batch method or the column chromatography. The contact of the absorbent may be carried out in single step or multiple steps.

The absorbent may be used in combination of a plural kinds selected according to the properties of the saturated hydrocarbon compound, and examples thereof include silica gel, activated carbon, alumina (activated alumina), zeolite, molecular sieves, and the like.

As the specific combination of the absorbent, the combination of activated carbon as the first absorbent and silica gel or alumina as the second absorbent may be exemplified. With the combination, the purity and transmittance of the saturated hydrocarbon compound can be further surely increased.

The absorbent may be formed, for example, in a particle form. Accordingly, the absorbent can be easily filled to the predetermined region of the supply system of the liquid for immersion exposure in the exposure device, and the specific surface area of the absorbent can be increased.

The purification process of the liquid for immersion exposure may further include the process of bringing the saturated hydrocarbon compound into contact with the third or from the third to the nth (n is an integer number of 4 or more) absorbent. Accordingly, even in the case where a plurality of impurities is contained in the saturated hydrocarbon compound, these impurities can be removed more efficiently.

The process of bringing the saturated hydrocarbon compound into contact with the third or from the third to the nth (n is an integer number of 4 or more) absorbent may be the same process as the process of bring the saturated hydrocarbon compound into contact with the first or the second absorbent or the different process as the process of bring the saturated hydrocarbon compound into contact with the first or the second absorbent. The third or the nth absorbent may be those having a function as a filtering medium capable of physically filtering fine particles, the other absorbents, and the like contained in the liquid to be separated.

An example of the method in which the process of bringing the saturated hydrocarbon compound into the third absorbent is same as the process of bringing the saturated hydrocarbon compound into the first or second absorbent may be the method including a mixing the first, second, and third absorbent to contact with the saturated hydrocarbon compound. Alternatively, the saturated hydrocarbon compound may be brought into contact with the mixture of the first and third absorbents, and then the saturated hydrocarbon compound may be brought into contact with the second absorbent.

An example of the method in which the process of bringing the saturated hydrocarbon compound into the third absorbent is the different process as the process of bringing the saturated hydrocarbon compound into the first or second absorbent may be the method bringing the saturated hydrocarbon compound into contact with the absorbent in the predetermined order, wherein the first absorbent, the second absorbent, and the third absorbent is placed in the separate spaces. More specifically, the process may include bringing the saturated hydrocarbon compound into contact with the first, third, and the second absorbent in the order, by the use of activated carbon as the first absorbent, silica gel as the second absorbent, and alumina as the third absorbent.

In addition, in the case of bringing the saturated hydrocarbon compound into contact with the four or more kinds of absorbents, the predetermined absorbent may be used appropriately in the combination, as the three kinds or less of absorbents are used.

As the purification device for producing the liquid for immersion exposure of the invention, there may be exemplified by the device in which the first absorbent is coexisted in a raw material tank with a raw material liquid which are then stirred, the mixture is transferred and passed through a column filled with the second absorbent, and the resultant is reserved as the immersion liquid in a reserving tank. As mentioned above, the liquid may be continuously passed through the column filled with the third and further the nth (n is an integer number of 4 or more) absorbent followed by the second absorbent.

In addition, a plurality of absorbents may be filled in one column. Also, when a liquid passed through the column is subjected to sampling and the purity thereof is determined in accordance with gas chromatography, transmission spectrum technique or the like, and this sampled liquid has an impurity with a concentration equal to or below the concentration mentioned above or a transparency not equal to or not above the predetermined value, there may be employed a circulation system which allows re-passing through the column filled with the absorbent.

Accordingly, the transparent liquid having high refractive index which exhibits the same transmittance to and higher refractive index than the purified water can be more easily provided. The application of the liquid to the conventional type immersion exposure tool makes finer resolution possible, as compare with the case of employing purified water, thus the liquid can be used for production of a highly integrated and highly densified electronic device.

In the above mentioned purification process, in the case where the purity of the raw material is low, the other purification and new synthesis method may be also employed as necessary. The purification method and synthesis method are not particularly limited, but for the purification, there may be employed, for example, a purification including adding a commercial product to an activated carbon or silica gel gas chromatography and subjecting distillation to give a high purity. An example of new synthesis include the process subjecting the compound having an unsaturated bond wherein the carbon backbone structure is same as the target compound to a hydrogen reduction to synthesize the target compound and purifying the compound in the same manner as above.

In the first purification, the saturated hydrocarbon compound having the impurity concentration in the range of the above mentioned concentration or less can be obtained by bringing the saturated hydrocarbon compound into contact with at least the first and second absorbent. However, when the saturated hydrocarbon compound which had been purified by the present method is used for the exposure after being re-purified after an exposure, the compound can be brought into contact with at least one absorbent.

The liquid for immersion exposure of the invention may be the liquid which is brought into contact with the absorbent, after the ArF laser is irradiated. Examples of the saturated hydrocarbon compound which is the main component include various saturated hydrocarbon compounds as described above, but more specifically include trans-decahydronaphthalene and bicyclohexyl.

In the liquid for immersion exposure of the invention, the saturated hydrocarbon compound which is the main component may be trans-decahydronaphthalene which is brought into contact with the absorbent, after the ArF laser is irradiated; (ii) the compound having no conjugated unsaturated bond but having a non-conjugated unsaturated bond may be at least one of octahydronaphthalenes and oxodecahydronaphthalenes; and (iv) the heterocyclic compound, the alcohols, the ethers, and the halogen-containing compound, other than above compounds (i) to (iii), may be hydroxydecahydronaphthalenes.

In the liquid for immersion exposure of the invention, the saturated hydrocarbon compound which is the main component may be bicyclohexyl which is brought into contact with the absorbent, after the ArF laser is irradiated, (ii) the compound having no conjugated unsaturated bond but having a non-conjugated unsaturated bond may be at least one of a cyclohexene, a cyclohexylcyclohexenes, and a dicyclohexenyls, and (iv) the heterocyclic compound, the alcohols, the ethers, and the halogen-containing compound, other than above compounds (i) to (iii), may be hydroxyhexylcyclohexanes.

### EXAMPLES

The present invention will be explained in detail with reference to Examples, but the invention is not limited by these.

Hereinafter, the concentration of impurity was determined by gas chromatography (column: SUPELCOEQUITY-1; inner diameter of 0.25 mm; length of 60 m; film thickness of 0.25 μm, temperature of 40° C. to 300° C.; temperature increasing rate of 10° C./minute, detection FID (Flame Ionization Detector: hydrogen flame ionization detector)).

For the transmittance of light, a sample was placed in a quartz cell having the optical path length of 10 mm with a cap, a nitrogen-bubbling was subjected for 30 minutes or more, and then the measurement was carried out using the same type of a cell filled with nitrogen as a reference, by the use of the ultraviolet-visible spectrophotometer (U-3010 manufactured by Hitachi, Ltd.), in accordance with the transmittance measurement mode.

For the refractive index in 193 nm, the value in 193.4 nm wavelength at 23° C. was measured by the use of a goniometer-spectrometer (type 1 UV-VIS-IR manufactured by MOLLER-WEDEL in Germany) in accordance with a minimum angle of deviation method. For the refractive index in D line (589 nm), the value at 25° C. was measured by the use of a multiple wavelength Abbe refractometer (DR-M2 manufactured by Atago Co., Ltd.).

In the following examples, experimental examples, and comparative examples, the following absorbents were used for the purification.

Silica gel: Wako gel C-200, manufactured by Wako Pure Chemical Industries, Ltd.

Alumina: Alumina A, acidity Super-I, manufactured by MERCKICN Corp.

Activated carbon: RO, pellet, manufactured by Norit, Inc.

### Example 1

To 10 parts by weight of commercially available trans-decahydronaphthalene (manufactured by Tokyo Chemical Industry Co., Ltd.), 1 part by weight of the activated carbon was added, the mixture was stirred for 24 hours at room temperature, and then the resultant was subjected to an absorptive filtration twice by the use of columns respectively employing 0.5 parts by weight of alumina in the former stage and 2 parts by weight of silica gel in the subsequent stage, to decrease the impurities as shown in. Table 1. The results after the purification (Example 1) are shown in Table 1 along with the results before the purification.

[Table 1]

TABLE 1

| | Impurity (μg/mL) | | | | | | Transmittance |
|---|---|---|---|---|---|---|---|
| | A | B | C | D | E | F | (%/mm) |
| Before | 3.8 | 65 | 310 | 30 | 18 | 40 | 1 |
| purification | | | | | | | |
| After | <0.1 | <0.5 | <0.5 | <0.2 | <0.2 | <0.3 | 98 |
| purification | | | | | | | |

Meanwhile, impurities A to F in Table 1 are following materials, respectively.

A: Toluene

B: 1-octene

C: 2-octene

D: 2,4-dimethylcyclohexanol

E: Tetrahydronaphthalene

F: Bis(2-ethylhexyl) phthalate

Among the above impurities, the components A, E, and F are classified as (i) mentioned above, the components B and C are classified as (ii) mentioned above, and the component D is classified as (iv) mentioned above.

In Table 1 and other Tables in the specification, “<” indicates the impurity concentration below the measurable limits.

Accordingly, the liquid exhibiting the transmittance of 98%/mm in 193 nm was obtained. From the measurement of the refractive index, high value of 1.64 was obtained.

In the liquid after purification, amines were not detected.

### Experimental Example 1

To the trans-decahydronaphthalene purified according to the Example 1, the impurity was added to measure the transmittance. As the result, the relations as shown in Table 2 were obtained. The refractive index of the samples 1, 2, 6, 10, 14, and 18 shown in Table 2 in D line (589 nm) was 1.47. As the refractive index of the sample 1 in 193 nm was 1.64, it is estimated that the refractive index of the samples 2, 6, 10, 14, and 18 in 193 nm are 1.6 or more.

[Table 2]

TABLE 2

| | Impurities (μg/mL) | | | | | | Transmittance |
|---|---|---|---|---|---|---|---|
| | A | B | C | D | E | F | (%/mm) |
| Sample 1 | <0.1 | <0.5 | <0.5 | <0.2 | <0.2 | <0.3 | 98 |
| Sample 2 | 0.1 | <0.5 | <0.5 | <0.2 | <0.2 | <0.3 | 98 |
| Sample 3 | 1 | <0.5 | <0.5 | <0.2 | <0.2 | <0.3 | 90 |
| Sample 4 | 2 | <0.5 | <0.5 | <0.2 | <0.2 | <0.3 | 81 |
| Sample 5 | 3 | <0.5 | <0.5 | <0.2 | <0.2 | <0.3 | 73 |
| Sample 6 | <0.1 | <0.5 | <0.5 | <0.2 | 0.1 | <0.3 | 98 |
| Sample 7 | <0.1 | <0.5 | <0.5 | <0.2 | 1 | <0.3 | 90 |
| Sample 8 | <0.1 | <0.5 | <0.5 | <0.2 | 2 | <0.3 | 82 |
| Sample 9 | <0.1 | <0.5 | <0.5 | <0.2 | 3 | <0.3 | 75 |
| Sample 10 | <0.1 | <0.5 | <0.5 | <0.2 | <0.2 | 0.1 | 98 |
| Sample 11 | <0.1 | <0.5 | <0.5 | <0.2 | <0.2 | 1 | 97 |
| Sample 12 | <0.1 | <0.5 | <0.5 | <0.2 | <0.2 | 2 | 94 |
| Sample 13 | <0.1 | <0.5 | <0.5 | <0.2 | <0.2 | 10 | 77 |
| Sample 14 | <0.1 | 1 | <0.5 | <0.2 | <0.2 | <0.3 | 98 |
| Sample 15 | <0.1 | 10 | <0.5 | <0.2 | <0.2 | <0.3 | 94 |
| Sample 16 | <0.1 | 30 | <0.5 | <0.2 | <0.2 | <0.3 | 82 |
| Sample 17 | <0.1 | 40 | <0.5 | <0.2 | <0.2 | <0.3 | 76 |
| Sample 18 | <0.1 | <0.5 | <0.5 | 3 | <0.2 | <0.3 | 98 |
| Sample 19 | <0.1 | <0.5 | <0.5 | 50 | <0.2 | <0.3 | 96 |
| Sample 20 | <0.1 | <0.5 | <0.5 | 100 | <0.2 | <0.3 | 93 |
| Sample 21 | <0.1 | <0.5 | <0.5 | 400 | <0.2 | <0.3 | 77 |

Meanwhile, impurities A to F in Table 2 are following materials, respectively, as the same as Table 1.

A: Toluene

B: 1-octene

C: 2-octene

D: 2,4-dimethylcyclohexanol

E: Tetrahydronaphthalene

F: Bis(2-ethylhexyl) phthalate

In Table 2, among the samples 1 to 21, the sample 1 is the sample to which the impurity is not added.

The samples 2 to 5 are the samples to which A (toluene) is added at the predetermined concentration.

The samples 6 to 9 are the samples to which E (tetrahydronaphthalene) is added at the predetermined concentration.

The samples 10 to 13 are the samples to which F (Bis(2-ethylhexyl) phthalate) is added at the predetermined concentration.

The samples 14 to 17 are the samples to which B (1-octene) is added at the predetermined concentration.

The samples 18 to 21 are the samples to which D (2,4-dimethylcyclohexanol) is added at the predetermined concentration.

### Example 2

To 10 parts by weight of commercially available bicyclohexyl (manufactured by Tokyo Chemical Industry Co., Ltd.), 1 part by weight of the activated carbon was added, the mixture was stirred for 24 hours at room temperature, and then resultant was subjected to the absorptive filtration three times by the use of the columns respectively employing 0.5 parts by weight of alumina in the former stage and 2 parts by weight of silica gel in the subsequent stage, to decrease the impurities as shown in Table 3. The results after the purification (Example 2) are shown in Table 3 along with the results before the purification.

[Table 3]

TABLE 3

| | Impurities (μg/mL) | | | | | Transmittance |
|---|---|---|---|---|---|---|
| | G | H | I | J | K | (%/mm) |
| Before | 60 | 1.8 | 2.5 | 70 | 150 | 1 |
| purification | | | | | | |
| After | <0.1 | <0.1 | <0.1 | <0.1 | <0.1 | 99 |
| purification | | | | | | |

Meanwhile, impurities G to K in Table 3 are following materials, respectively.

G: Tetrahydrofuran

H: Cyclohexylmethanol

I: Methyl cyclohexane carboxylate

J: Biphenyl

K: 2,6-di-tert-butyl-p-cresol

Among the above impurities, the components G and H are classified as (iv) mentioned above, the component I is classified as (ii) mentioned above, and the components J and K are classified as (i) mentioned above.

Accordingly, the liquid exhibiting the transmittance of 99%/mm in 193 nm was obtained. From the measurement of the refractive index, high value of 1.64 was obtained.

In the liquid after purification, amines were not detected.

### Experimental Example 2

To the bicyclohexyl purified according to the Example 2, the impurity was added to measure the transmittance. As the result, the relations as shown in Table 4 were obtained. The refractive index of the samples 22, 27, and 31 shown in Table 4 in D line (589 nm) was 1.48. As the refractive index of the sample 22 in 193 nm was 1.64, it is estimated that the refractive index of the samples 27 and 31 in 193 nm are 1.6 or more.

[Table 4]

TABLE 4

| | Impurities (μg/mL) | | | | | Transmittance |
|---|---|---|---|---|---|---|
| | G | H | I | J | K | (%/mm) |
| Sample 22 | <0.1 | <0.1 | <0.1 | <0.1 | <0.1 | 99 |
| Sample 23 | 3 | <0.1 | <0.1 | <0.1 | <0.1 | 98 |
| Sample 24 | 50 | <0.1 | <0.1 | <0.1 | <0.1 | 91 |
| Sample 25 | 100 | <0.1 | <0.1 | <0.1 | <0.1 | 83 |
| Sample 26 | 150 | <0.1 | <0.1 | <0.1 | <0.1 | 77 |
| Sample 27 | <0.1 | <0.1 | <0.1 | 0.1 | <0.1 | 98 |
| Sample 28 | <0.1 | <0.1 | <0.1 | 1 | <0.1 | 91 |
| Sample 29 | <0.1 | <0.1 | <0.1 | 2 | <0.1 | 83 |
| Sample 30 | <0.1 | <0.1 | <0.1 | 3 | <0.1 | 77 |
| Sample 31 | <0.1 | <0.1 | <0.1 | <0.1 | 0.1 | 98 |
| Sample 32 | <0.1 | <0.1 | <0.1 | <0.1 | 1 | 96 |
| Sample 33 | <0.1 | <0.1 | <0.1 | <0.1 | 2 | 92 |
| Sample 34 | <0.1 | <0.1 | <0.1 | <0.1 | 8 | 73 |

Meanwhile, impurities G to K in Table 4 are following materials, respectively, as same as the Table 3.

G: Tetrahydrofuran

H: Cyclohexylmethanol

I: Methyl cyclohexane carboxylate

J: Biphenyl

K: 2,6-di-tert-butyl-p-cresol

In Table 4, among the samples 22 to 34, the sample 22 is the sample to which the impurity is not added.

The samples 23 to 26 are the samples to which G (tetrahydrofuran) is added at the predetermined concentration.

The samples 27 to 30 are the samples to which J (biphenyl) is added at the predetermined concentration.

The samples 31 to 34 are the samples to which K (2,6-di-tert-butyl-p-cresol) is added at the predetermined concentration.

### Experimental Example 3

To the bicyclohexyl purified according to the Example 2, the impurity was added to measure the transmittance. As the result, the relations as shown in Table 5 were obtained. The refractive index of the samples 35, 36, 40, and 44 shown in Table 5 in D line (589 nm) was 1.48. As the refractive index of the sample 35 in 193 nm was 1.64, it is estimated that the refractive index of the samples 36, 40, and 44 in 193 nm are also 1.6 or more.

[Table 5]

TABLE 5

| | Impurities (μg/mL) | | | Transmittance |
|---|---|---|---|---|
| | L | M | N | (%/mm) |
| Sample 35 | — | — | — | 99 |
| Sample 36 | 1 | — | — | 98 |
| Sample 37 | 5 | — | — | 96 |
| Sample 38 | 30 | — | — | 86 |
| Sample 39 | 50 | — | — | 79 |
| Sample 40 | — | 3 | — | 99 |
| Sample 41 | — | 50 | — | 93 |
| Sample 42 | — | 100 | — | 88 |
| Sample 43 | — | 220 | — | 78 |
| Sample 44 | — | — | 0.5 | 98 |
| Sample 45 | — | — | 5 | 93 |
| Sample 46 | — | — | 15 | 83 |
| Sample 47 | — | — | 20 | 79 |

Meanwhile, impurities L to N in Table 5 are following materials, respectively.

L: Acetone

M: Chloroform

N: Triethylamine

Among the above impurities, the component L is classified as (ii) mentioned above, the component M is classified as (iv) mentioned above, and the component N is classified as (iii) mentioned above.

In Table 5, among the samples 35 to 47, the sample 35 is the sample to which the impurity is not added.

The samples 36 to 39 are the samples to which L (acetone) is added at the predetermined concentration.

The samples 40 to 43 are the samples to which M (chloroform) is added at the predetermined concentration.

The samples 44 to 47 are the samples to which N (triethylamine) is added at the predetermined concentration.

### Comparative Example 1

10 parts by weight of commercially available trans-decahydronaphthalene was filtered by the use of 0.01 parts by weight of the silica gel. As the result, the impurities were decreased as shown in Table 6, while the transmittance in 193 nm was maintained at 25%/mm.

[Table 6]

TABLE 6

| | Impurities (μg/mL) | | | | | | Transmittance |
|---|---|---|---|---|---|---|---|
| | A | B | C | D | E | F | (%/mm) |
| Before | 3.8 | 65 | 310 | 30 | 18 | 40 | 1 |
| purification | | | | | | | |
| After | 3 | 0.7 | 1.8 | 1.5 | 11 | 35 | 25 |
| purification | | | | | | | |

Meanwhile, impurities A to F in Table 6 are following materials, respectively, as same as the Table 1.

A: Toluene

B: 1-octene

C: 2-octene

D: 2,4-dimethylcyclohexanol

E: Tetrahydronaphthalene

F: Bis(2-ethylhexyl) phthalate

### Example 3

To 10 parts by weight of commercially available bicyclohexyl (manufactured by Aldrich Co., Ltd.), 1 part by weight of the activated carbon was added, the mixture was stirred for 24 hours at room temperature, and then the resultant was subjected to the absorptive filtration twice by the use of the columns respectively employing 0.5 parts by weight of alumina in the former stage and 2 parts by weight of silica gel in the subsequent stage, to decrease the impurities as shown in Table 7. The results after the purification (Example 3) were shown in Table 7 along with the results before the purification.

[Table 7]

TABLE 7

| | Impurities (μg/mL) | | | | Transmittance |
|---|---|---|---|---|---|
| | F | G | K | O | (%/mm) |
| Before | 110 | 1600 | 140 | 23 | <1 |
| purification | | | | | |
| After | <0.1 | <0.1 | <0.1 | <0.1 | 99 |
| purification | | | | | |

Meanwhile, impurities F, G, K and O in Table 7 are following material, respectively.

F: Bis(2-ethylhexyl) phthalate

G: Tetrahydrofuran

K: 2,6-di-tert-butyl-p-cresol

O: n-butanol

Among the above impurities, the components G and O are classified as (iv) mentioned above, and the components F and K are classified as (i) mentioned above.

Accordingly, the liquid exhibiting the transmittance of 99%/mm in 193 nm was obtained. From the measurement of the refractive index, high value of 1.64 was obtained.

In the liquid after purification, amines were not detected.

### Example 4

The trans-decahydronaphthalene purified according to the Example 1 was placed in a quartz cell to be capped under nitrogen, and irradiated with ArF excimer laser (L5837 manufactured by Hamamatsu Photonics K.K.) (total energy amount of 6,000 mJ) under the condition of which the energy is not less than by two digits the usual exposure condition of about 10 mJ, as a simulation, to measure the transmittance of the sample. As the results, the transmittance of the samples were decreased to 93.7%/mm. 10 parts by weight of the samples were subjected to the absorptive filtration by the use of the column employing 1 part by weight of silica gel. Accordingly, the transmittance in 193 nm was recovered to 98%/mm or more. As the results of the analysis of the recovered liquid, the impurities corresponding to (i) to (iv) were not detected.

### Example 5

The bicyclohexyl purified according to the Example 2 was placed in a quartz cell to be capped under nitrogen, and irradiated with ArF excimer laser (L5837 manufactured by Hamamatsu Photonics K.K.) (total energy amount of 6,000 mJ) under the condition of which the energy is not less than by two digits the usual exposure condition of about 10 mJ, as a simulation, to measure the transmittance of the sample. As the results, the transmittance of the samples were decreased to 96.7%/mm. 10 parts by weight of the samples were subjected to the absorptive filtration by the use of the column employing 1 part by weight of silica gel. Accordingly, the transmittance in 193 nm was recovered to 99%/mm or more. As the results of the analysis of the recovered liquid, the impurities corresponding to (i) to (iv) were not detected.

According to the above mentioned examples, there is obtained the transparent liquid exhibiting high refractive index which indicates the same transmittance and higher refractive index than that of the pure water. Therefore, the application of the obtained liquid to the traditional immersion exposure device make finer resolution possible, as compare with the case of employing pure water, thereby using for manufacturing the highly integrated and highly densified electronic device.

1. A liquid for immersion exposure comprising a saturated hydrocarbon compound as the main component,
wherein the content of an impurity or impurities having an unsaturated bond or a heteroatom in its structure is respectively as follows:
(i) 2 μg/mL or less in total for a compound having a conjugated unsaturated bond;
(ii) 30 μg/mL or less in total for a compound having no conjugated unsaturated bond but having a non-conjugated unsaturated bond;
(iii) 15 μg/mL or less in total for amines having no unsaturated bond; and
(iv) 100 μg/mL or less in total for a heterocyclic compound, alcohols, ethers and a halogen-containing compound, other than said compounds (i) to (iii).

2. The liquid for immersion exposure as claimed in claim 1,
wherein said content of an impurity or impurities is 100 μg/mL or less in total for said (i) to (iv).

3. The liquid for immersion exposure as claimed in claim 1,
wherein said impurity is at least one selected from the group consisting of an aromatic compound, a heterocyclic compound, alkenes, alkynes, alcohols, ethers, a carbonyl compound, a halogen-containing compound, and amines.

4. The liquid for immersion exposure as claimed in claim 3,
wherein said heterocyclic compound is at least one selected from the group consisting of an oxygen-containing cyclic compound, a sulfur-containing cyclic compound, and a nitrogen-containing cyclic compound.

5. The liquid for immersion exposure as claimed in claim 1,
wherein said saturated hydrocarbon compound which is the main component is trans-decahydronaphthalene.

6. The liquid for immersion exposure as claimed in claim 5,
wherein said saturated hydrocarbon compound which is the main component is trans-decahydronaphthalene,
said (i) compound having a conjugated unsaturated bond is at least one selected from the group consisting of toluene, tetrahydronaphthalene, and phthalic esters;
said (ii) compound having no conjugated unsaturated bond but having a non-conjugated unsaturated bond is octenes; and
said (iv) a heterocyclic compound, alcohols, ethers and a halogen-containing compound, other than said compounds (i) to (iii) is cyclohexanols.

7. The liquid for immersion exposure as claimed in claim 1,
wherein said saturated hydrocarbon compound which is the main component is bicyclohexyl.

8. The liquid for immersion exposure as claimed in claim 7,
wherein said saturated hydrocarbon compound which is the main component is bicyclohexyl,
said (i) compound having a conjugated unsaturated bond is at least one selected from the group consisting of biphenyl, cresols, and phthalic esters;
said (ii) compound having no conjugated unsaturated bond but having a non-conjugated unsaturated bond is methyl cyclohexane carboxylic acid; and
said (iv) a heterocyclic compound, alcohols, ethers and a halogen-containing compound, other than said compounds (i) to (iii) is at least one selected from the group consisting of tetrahydrofuran, cyclohexyl methanol, and n-butanol.

9. An immersion exposure method employing the liquid for immersion exposure as claimed in claim 1.

10. An immersion exposure method employing the liquid for immersion exposure as claimed in claim 3.

11. An immersion exposure method employing the liquid for immersion exposure as claimed in claim 5.

12. An immersion exposure method employing the liquid for immersion exposure as claimed in claim 7.

13. The liquid for immersion exposure as claimed in claim 2,
wherein said impurity is at least one selected from the group consisting of an aromatic compound, a heterocyclic compound, alkenes, alkynes, alcohols, ethers, a carbonyl compound, a halogen-containing compound, and amines.

14. The liquid for immersion exposure as claimed in claim 2,
wherein said saturated hydrocarbon compound which is the main component is trans-decahydronaphthalene.

15. The liquid for immersion exposure as claimed in claim 2,
wherein said saturated hydrocarbon compound which is the main component is bicyclohexyl.

16. An immersion exposure method employing the liquid for immersion exposure as claimed in claim 2.
